(19) United States
(12) Patent Application Publication
(10) Pub. No.: US 2011/0248733 A1
(43) Pub. Date: Oct. 13, 2011

(54) TEST APPARATUS AND TEST METHOD

(75) Inventor: Shusuke KANTAKE, Gunma (JP)

(73) Assignee: ADVANTEST CORPORATION, Tokyo (JP)

(21) Appl. No.: 13/023,431

(22) Filed: Feb. 8, 2011

Related U.S. Application Data
(63) Continuation of application No. PCT/JP2009/003954, filed on Aug. 19, 2009.

(30) Foreign Application Priority Data
Aug. 19, 2008 (JP) 2008-211123

(51) Int. Cl. G01R 31/00

(52) U.S. Cl. 324/750.01

(57) ABSTRACT

A test apparatus that tests a device under test having a plurality of blocks operating asynchronously, based on a signal received from outside, the test apparatus comprising a plurality of domain test units corresponding respectively to the blocks; and a main body unit that controls the domain test units. The main body unit includes a reference operation clock generating section that generates a reference operation clock supplied to each domain test unit, and a test start signal generating section that generates a test start signal instructing each domain test unit to start the testing. Each domain test unit includes a test clock generating section that generates a test clock based on the reference operation clock, and generates a test signal for testing the corresponding block based on the test clock obtained by the test clock generating section, and each domain test unit starts generating the test signal on a condition that the test start signal is received.

### BACKGROUND

1. Technical Field

The present invention relates to a test apparatus and a test method for testing a device under test.

2. Related Art

A test apparatus for testing a device under test such as an electronic device performs testing by supplying the device under test with a test signal having a frequency corresponding to the operation frequency of the device under test, and comparing the output signal of the device under test to a predetermined expected value signal. Patent Document 1, for example, describes a test apparatus comprising a test module that supplies a first test pattern based on a first reference clock having a predetermined frequency, a test module that supplies a second test pattern based on a second reference clock having a predetermined frequency, and a clock supplying section that generates the first reference clock and the second reference clock.

The test apparatus of Citation 1 includes a first phase synchronizing section that synchronizes the second reference clock with a first test rate that is generated based on the first reference clock and that indicates a period with which the first test pattern it so be supplied to the device under test. As a result, for a device under test that includes a plurality of blocks having different operational frequencies, the test apparatus can perform testing by having the blocks operate simultaneously and can perform a reproducible test.
Patent Document 1: Japanese Patent Application Publication No. 2004-361343

The test apparatus of Citation 1, however, requires more test modules and more clock supplying sections for larger devices under test. Furthermore, in the test apparatus of Citation 1, a second reference clock supplied from the clock supplying section is used as a common reference clock for a plurality of domains. Therefore, when there are many domains or when the test rates of domains are slightly skewed from being integer multiples of each other, the frequency of the second reference clock is decreased to compensate. For example, when the frequency of the test period signal of the first domain is 200 Mbps and the frequency of the test period signal of the second domain is 401 Mbps, the frequency of the common reference signal is set to the low value of 1 MHz.

In the test apparatus of Citation 1, the second reference clock is used as the reference clock for the PLL circuits provided in each domain, and therefore, when the second reference clock does not have a frequency that is approximately 10 times the PLL band, the spurious frequency in the reference frequency cannot be sufficiently cut off. As a result, the accuracy of the PLL circuit is lowered.

### SUMMARY

Therefore, it is an object of an aspect of the innovations herein to provide a test apparatus and a test method, which are capable of overcoming the above drawbacks accompanying the related art. The above and other objects can be achieved by combinations described in the independent claims. The dependent claims define further advantageous and exemplary combinations of the innovations herein.

According to a first aspect related to the innovations herein, provided is a test apparatus that tests a device under test having a plurality of blocks operating asynchronously, based on a signal received from outside, the test apparatus comprising a plurality of domain test units provided to correspond respectively to the blocks; and a main body unit that controls the domain test units. The main body unit includes a reference operation clock generating section that generates a reference operation clock supplied to each domain test unit, and a test start signal generating section that generates a test start signal instructing each domain test unit to start the testing. Each domain test unit includes a test clock generating section that generates a test clock based on the reference operation clock, and generates a test signal for testing the corresponding block based on the test clock obtained by the test clock generating section, and each domain test unit starts generating the test signal on a condition that the test start signal is received.

In the test apparatus, each domain test unit may further include a multiplied test clock generating section that generates a multiplied test clock having a frequency that is an integer multiple of the test clock obtained by the test clock generating section, and each domain test unit may generate the test signal for testing the corresponding block according to a period of the multiplied test clock obtained by the multiplied test clock generating section.

According to a second aspect related to the innovations herein, provided is a test method for testing a device under test using a test apparatus that includes a plurality of domain test units provided to correspond respectively to a plurality of blocks of the device under test and a main body unit that controls the domain test units. The test method comprises using the main body unit to generate a reference operation clock and supply the reference operation clock to each domain test unit; using the main body unit to generate a test start signal instructing each domain test unit to start the testing; using the main body unit to supply the test start signal to each domain test unit; causing each domain test unit to generate a test clock based on the reference operation clock; causing each domain test unit to start generating a test signal for testing the corresponding block, based on the test clock, on a condition that the test start signal is received; and causing each domain test unit to use the test signal to test the corresponding block.

The test method may further comprise causing each domain test unit to generate a multiplied test clock having a frequency that is an integer multiple of a frequency of the test clock, and causing each domain test unit to generate a test signal for testing the corresponding block according to a period of the multiplied test clock.

According to a third aspect related to the innovations herein, provided is a test apparatus comprising a test domain that includes: a first period signal generating section that receives a phase change signal and adjusts a phase of a period signal generated thereby, based on the phase change signal; a second period signal generating section that receives, as a reference clock, the period signal generated by the first period signal generating section, and generates a multiplied-period signal with a frequency that is an integer multiple of the frequency of the period signal; and a testing section that receives, as a test period signal, the multiplied-period signal generated by the second period signal generating section, and tests the device under test according to a period of the test period signal.

The test apparatus may further comprise an other test domain that includes: a third period signal generating section that receives the phase change signal and adjusts a phase of an other period signal generated thereby, based on the phase change signal; and an other testing section that receives, as an other test period signal, the other period signal generated by the third period signal generating section, and tests an other device under test according to a period of the other test period signal. The test apparatus may synchronize the test period signal of the test domain and the other test period signal of the other test domain by commonly using the phase change signal. The first period signal generating section may generate, as the period signal, a period pulse signal that transitions at a transition timing of an operation clock and phase difference data that indicates a phase difference between a period timing of the period signal and a transition timing of the period pulse signal.

The test apparatus may fix a multiplication rate of the second period signal generating section and change a period of the multiplied-period signal using a period of the period signal generated by the first period signal generating section.

According to a fourth aspect related to the innovations herein, provided is a test method comprising receiving a phase change signal and adjusting a phase of a generated period signal based on the phase change signal; receiving the adjusted period signal as a reference clock, and generating a multiplied-period signal with a frequency that is an integer multiple of the frequency of the period signal; and testing a device under test according to a period of the multiplied-period signal.

The summary clause does not necessarily describe all necessary features of the embodiments of the present invention.

The present invention may also be a sub-combination of the features described above.

### BRIEF DESCRIPTION OF THE DRAWINGS

FIG. 1 is a schematic view of an exemplary configuration of a test apparatus 100 according to an embodiment of the present invention.

FIG. 2 is a schematic view of the configuration of a first domain 104.

FIG. 3 is a schematic view of an exemplary configuration of a second domain 106.

FIG. 4 is a schematic view of an exemplary first period signal 40.

### DESCRIPTION OF EXEMPLARY EMBODIMENTS

Hereinafter, an embodiment of the present invention will be described. The embodiment does not limit the invention according to the claims, and all the combinations of the features described in the embodiment are not necessarily essential to means provided by aspects of the invention.

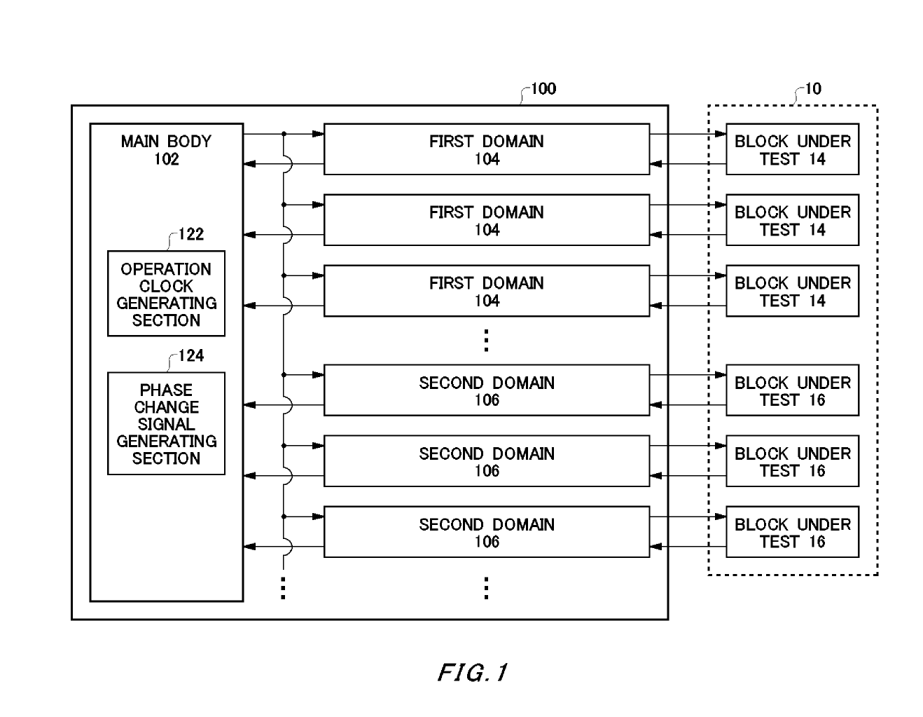

FIG. 1 is a schematic view of an exemplary configuration of a test apparatus 100 according to an embodiment of the present invention. The test apparatus 100 tests a device under test 10. The device under test 10 includes blocks under test 14 and blocks under test 16. The blocks under test 14 and the blocks under test 16 may be a plurality of blocks having different operational frequencies in the device under test 10. For example, if the device under test 10 includes a central processing unit and a memory control device with different operational frequencies, the blocks under test 14 may be the central processing unit and the blocks under test 16 may be the memory control device.

The present embodiment describes an example in which the device under test 10 includes a plurality of blocks with different operational frequencies, but the device under test 10 is not limited to this configuration. For example, the device under test 10 may be a single semiconductor chip.

The test apparatus 100 includes a main body 102, first domains 104, and second domains 106. Each first domain 104 may be an example of a test domain. Each second domain 106 may be an example of an other test domain. The first domains 104 and the second domains 106 are an example of a domain testing unit. In the present embodiment, the test apparatus 100 includes a plurality of first domains 104 and a plurality of second domains 106.

The test apparatus 100 may test a device under test including a plurality of blocks that operate asynchronously, based on a signal supplied thereto from the outside. For example, when the blocks under test 14 and the blocks under test 16 operate asynchronously, the first domains 104 and the second domains 106 may be provided to correspond respectively to the blocks under test 14 and the blocks under test 16.

The main body 102 may control the first domains 104 and the second domains 106. The main body 102 may include an operation clock generating section 122 that generates an operation clock supplied to the first domains 104 and the second domains 106. The operation clock may be an example of a clock serving as a reference for operation of the test apparatus 100. The operation clock may be an example of a reference operation clock.

The main body 102 generates a phase change signal PCsig and supplies this signal to the first domains 104 and the second domains 106. The phase change signal PCsig adjusts the phases of the first domains 104 and the second domains 106.

The phase change signal PCsig may be provided in order to align the timings at which the first domains 104 and the second domains 106 begin testing. The first test period signal and second test period signal described below may be synchronized using a common phase change signal PCsig. As a result, synchronization between the phases of the first domains 104 and the second domains 106 can be managed easily. The main body 102 may store the test results received from the first domains 104 and the second domains 106.

The phase change signal PCsig may be an example of a test start signal instructing the first domains 104 and the second domains 106 to start testing. The main body 102 may include a phase change signal generating section 124 that generates the phase change signal PCsig. The phase change signal generating section 124 may be an example of a test start signal generating section. The main body 102 may supply the test start signal to the first domains 104 and the second domains 106. When resuming testing that was temporarily stopped, the main body 102 may supply the phase change signal PCsig in order to instruct the first domains 104 and the second domains 106 to resume testing. The main body 102 may be an example of a main body unit.

The first domains 104 test the blocks under test 14. For example, each first domain 104 may test the block under test 14 by supplying the block under test 14 with a first test signal and comparing an output signal from the block under test 14 to a predetermined first expected value signal. The first test signal may have a frequency corresponding to the operation frequency of the block under test 14. The first domain 104 may internally generate a first test period signal designating the period of the first test signal. The first domain 104 may test the block under test 14 according to the period of the first test period signal. The first domain 104 may supply the main body 102 with the obtained test results. The first test period signal may be an example of a test clock.

The second domains 106 test the blocks under test 16. For example, each second domain 106 may test the block under test 16 by supplying the block under test 16 with a second test signal and comparing an output signal from the block under test 16 to a predetermined second expected value signal. The second test signal may have a frequency corresponding to the operation frequency of the block under test 16. The second domain 106 may internally generate a second test period signal designating the period of the second test signal. The second domain 106 may test the block under test 16 according to the period of the second test period signal. The second domain 106 may supply the main body 102 with the obtained test results. The second test period signal may be an example of a test clock.

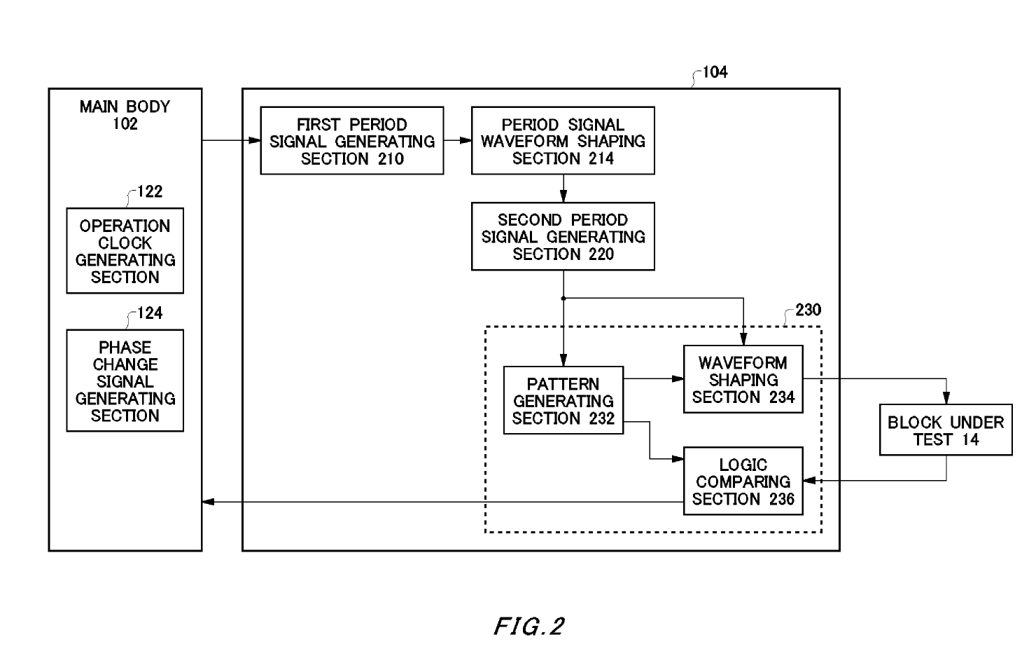

FIG. 2 is a schematic view of the configuration of a first domain 104. The first domain 104 includes a first period signal generating section 210, a period signal waveform shaping section 214, a second period signal generating section 220, and a testing section 230.

The first period signal generating section 210 receives the phase change signal PCsig from the main body 102. The first period signal generating section 210 generates a first period signal. The first period signal designates the period of the reference clock of the second period signal generating section 220. The phase of the first period signal is adjusted based on the phase change signal PCsig. The first period signal may be an example of a period signal. The first period signal may include a period pulse signal that transitions at the transition timing of the operation clock and phase difference data indicating a phase difference between the period timing of the first period signal and the transition timing of the period pulse signal.

The first period signal generating section 210 supplies the period signal waveform shaping section 214 with the first period signal. With the above configuration, the frequency of the first period signal can be selected without referencing the relationship between the test rate of the first domain 104 and the test rate of the second domain 106.

The period signal waveform shaping section 214 shapes the period signal supplied from the first period signal generating section 210 to have a waveform suitable for the reference clock of the second period signal generating section 220. For example, the period signal waveform shaping section 214 may shape the waveform based on the phase difference data and the period pulse signal supplied from the first period signal generating section 210. The period signal waveform shaping section 214 supplies the shaped waveform to the second period signal generating section 220.

The second period signal generating section 220 receives, as the reference clock, the first period signal generated by the first period signal generating section 210. The second period signal generating section 220 generates a multiplied-period signal whose frequency is an integer multiple of the frequency of the first period signal. The second period signal generating section 220 supplies the multiplied-period signal to the testing section 230. The multiplied-period signal designates the period of the first test signal supplied to the block under test 14. The second period signal generating section 220 may be a PLL circuit, and may be synchronized with the phase of the first period signal to accurately generate the multiplied-period signal having a frequency that is an integer multiple of the frequency of the first period signal.

The first period signal and the reference clock generated based on the first period signal are examples of test clocks. The first period signal generating section 210 may be an example of a test clock generating section. The first period signal generating section 210 may use a counter, a flip-flop circuit, or the like to generate a signal with a desired waveform or a desired frequency, based on the operation clock. The present embodiment describes an example in which the above reference clock is generated by the period signal waveform shaping section 214 shaping a waveform based on the first period signal generated by the first period signal generating section. However, the method for generating the reference clock is not limited to this. For example, the first period signal generating section 210 may output a reference clock with a shaped waveform.

The multiplied-period signal may have a frequency that is an integer multiple of the reference frequency generated based on the first period signal. The second period signal generating section 220 may be an example of a multiplied test clock generating section. The reference clock generated based on the first period signal may have a frequency that is M/N times the frequency of the operation clock supplied from the main body 102. Here, M and N are natural numbers, and are not 0.

The period of the multiplied-period signal can be adjusted by changing at least one of the first period signal and the multiplication rate of second period signal generating section 220. For example, the multiplication rate of the second period signal generating section 220 may be fixed and the period of the multiplied-period signal may be changed according to the period of the first period signal generated by the first period signal generating section 210. In other words, the period of the multiplied-period signal may be adjusted by changing the period of the first period signal. At this time, if a PLL circuit is used as the second period signal generating section 220, the loop value of the PLL circuit is constant. As a result, the second period signal generating section 220 can be easily designed and the size of the hardware is decreased.

The testing section 230 receives, as the first test period signal, the multiplied-period signal generated by the second period signal generating section 220. The first test period signal designates the period of the first test signal supplied to the block under test 14. The testing section 230 tests the block under test 14 according to the period of the first test period signal.

The testing section 230 includes a pattern generating section 232, a waveform shaping section 234, and a logic comparing section 236. The pattern generating section 232 and the waveform shaping section 234 receive the multiplied-period signal from the second period signal generating section 220. The pattern generating section 232 generates a pattern signal corresponding to the first test signal, and supplies the pattern signal to the waveform shaping section 234. The pattern signal designates a data pattern of the first test signal. The pattern generating section 232 generates a first expected value signal corresponding to the first test signal, and supplies the first expected value signal to the logic comparing section 236.

The waveform shaping section 234 shapes the waveforms of the pattern signal supplied from the pattern generating section 232 and the multiplied-period signal supplied from the second period signal generating section 220 to be suitable for testing the block under test 14. The waveform shaping section 234 supplies the shaped waveforms to the block under test 14. The logic comparing section 236 receives the output signal of the block under test 14. The logic comparing section 236 compares the output signal of the block under test 14 to the first expected value signal supplied from the pattern generating section 232 to judge pass/fail of the block under test 14. The logic comparing section 236 may supply the test results to the main body 102.

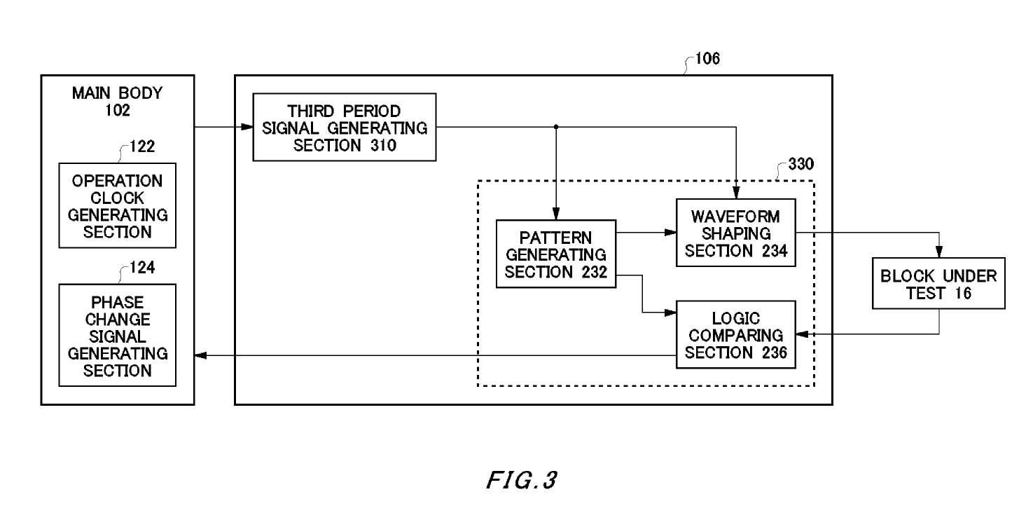

FIG. 3 is a schematic view of an exemplary configuration of a second domain 106. The second domain 106 includes a third period signal generating section 310 and a testing section 330. The third period signal generating section 310 has practically the same configuration as the first period signal generating section 210. The testing section 330 has the same configuration as the testing section 230, and includes a pattern generating section 232, a waveform shaping section 234, and a logic comparing section 236. The following describes only differing points between (i) the third period signal generating section 310 and the testing section 330 and (ii) the first period signal generating section 210 and the testing section 230.

The third period signal generating section 310 receives the phase change signal PCsig from the main body 102. The third period signal generating section 310 generates a second period signal. The second period signal designates the period of a second test signal supplied to the block under test 16. The second period signal may be an example of an other period signal. The third period signal generating section 310 supplies the second period signal to the testing section 330. The phase of the second period signal is adjusted based on the phase change signal PCsig. With the above configuration, the phase of the second test signal and the like can be adjusted while restricting effects on other elements of the test apparatus 100.

The second period signal may be an example of a test clock. The third period signal generating section 310 may be an example of a test clock generating section.

The testing section 330 receives, as the second test period signal, the second period signal generated by the third period signal generating section 310. The second test period signal designates the period of the second test signal supplied to the block under test 16. The testing section 330 tests the block under test 16 according to the period of the second test period signal. In the testing section 330, the pattern generating section 232 and the waveform shaping section 234 receive the second period signal supplied from the third period signal generating section 310.

In the testing section 330, the pattern generating section 232 generates a pattern signal corresponding to the second test signal and supplies this pattern signal to the waveform shaping section 234. The pattern generating section 232 generates a second expected value signal corresponding to the second test signal, and supplies the second expected value signal to the logic comparing section 236.

In the testing section 330, the waveform shaping section 234 shapes the waveforms of the pattern signal supplied from the pattern generating section 232 and the second period signal supplied from the third period signal generating section 310 to be suitable for testing the block under test 16. The waveform shaping section 234 supplies the block under test 16 with the shaped waveforms.

In the testing section 330, the logic comparing section 236 receives the output signal of the block under test 16. The logic comparing section 236 compares the output signal of the block under test 16 to the second expected value signal supplied from the pattern generating section 232 to judge pass/fail of the block under test 16.

The first domain 104 generates the first test signal for testing the block under test 14 based on the first period signal obtained from the first period signal generating section 210. The first domain 104 may generate the first test signal for testing the block under test 14 based on the multiplied-period signal obtained by the second period signal generating section 220. The second domain 106 generates the second test signal for testing the block under test 16 based on the second period signal obtained by the third period signal generating section 310. The first domain 104 and the second domain 106 may begin generating the first period signal and the second period signal based on the operation clock, on a condition that the phase change signal PCsig is received. The first domain 104 and the second domain 106 may begin generating the first test signal and the second test signal on a condition that the phase change signal PCsig is received.

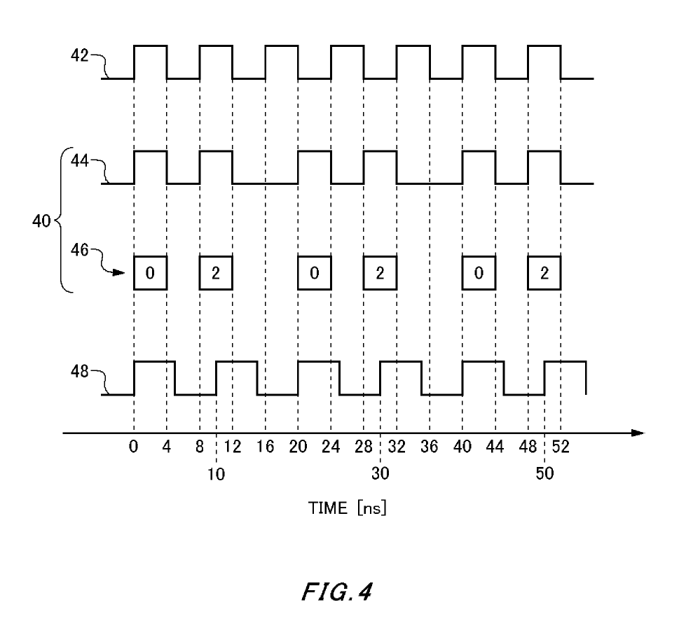

FIG. 4 is a schematic view of an exemplary first period signal 40 generated by the first period signal generating section 210. As shown in FIG. 4, the first period signal 40 may include a period pulse signal 44 that transitions at the transition timing of the operation clock 42 and phase difference data 46 indicating a phase difference between the period timing of the first period signal 40 and the transition timing of the period pulse signal 44. In other words, the first period signal generating section 210 may generate the period pulse signal 44 and the phase difference data 46 as the first period signal 40. The operation clock 42 may be an example of a reference operation clock.

As a result, the first period signal 40 can be generated to have a desired frequency, regardless of the frequency of the operation clock. As a result, even when the test rates of the domains differ slightly from being integer multiples of each other, the first period signal generating section 210 can generate the first period signal 40 based on the frequency of the first test period signal and the multiplication rate of the second period signal generating section 220, while ignoring the frequency of the second test period signal. The second period signal generated by the third period signal generating section 310 may have the same structure as the first period signal 40.

The following uses FIG. 4 to describe the period pulse signal 44 and the phase difference data 46 in a case where the frequency of the operation clock 42 is 125 MHz and the first period signal 40 is generated with a frequency of 100 MHz. At the time 0 ns, the period pulse signal 44 transitions from logic L to logic H at the same timing when the operation clock 42 transitions from logic L to logic H. At this time, the phase difference data 46 indicates 0 ns. As a result, simultaneously with the period pulse signal 44, the period timing of the first period signal 40 indicates a transition from logic L to logic H.

The period pulse signal 44 may be set to transition from logic H to logic L after a prescribed time has passed since transitioning from logic L to logic H. In the present example, the period pulse signal 44 is set to transition from logic H to logic L after 4 ns have passed since transitioning from logic L to logic H.

Next, at the time 8 ns, the period pulse signal 44 transitions from logic L to logic H. At this time, the phase difference data 46 indicates 2 ns. As a result, once a phase of 2 ns has passed after the period pulse signal 44 transitions from logic L to logic H, the period timing of the first period signal 40 indicates a transition from logic L to logic H.

In this way, the first period signal 40 including the period pulse signal 44 and the phase difference data 46 is generated. The first period signal 40 is supplied to the period signal waveform shaping section 214, and is shaped to have a waveform 48 suitable for use as the reference clock of the second period signal generating section 220. As shown in FIG. 4, the waveform 48 has a period of 10 ns.

With the above configuration, the test apparatus 100 can adjust as desired the phases of the first test period signal and the second test period signal. Therefore, by using a common phase change signal PCsig to synchronize the first test period signal and the second test period signal, phase synchronization between the first domains 104 and the second domains 106 can be easily managed even when the blocks under test 14 and the blocks under test 16 have different operational frequencies.

The present embodiment describes an example in which the test apparatus 100 includes a plurality of first domains 104 and second domains 106, but the test apparatus 100 is not limited to this configuration. For example, the test apparatus 100 may include just one first domain 104, or may include one each of the first domain 104 and the second domain 106.

The block under test 14 and the block under test 16 may be an example of a device under test. In the present embodiment, the test apparatus 100 uses a plurality of first domains 104 and second domains 106 to test different blocks within a single device under test. However, the test apparatus 100 is not limited to this. The test apparatus 100 may test identical types of devices under test, or may test different types of devices under test. The first domains 104 and the second domains 106 may test different blocks of different devices under test.

The above includes a description of the following test method. Described is a test method comprising receiving a phase change signal and adjusting a phase of a generated period signal based on the phase change signal; receiving the adjusted period signal as a reference clock, and generating a multiplied-period signal with a frequency that is an integer multiple of the frequency of the period signal; and testing a device under test according to a period of the multiplied-period signal.

The above also includes a description of the following test method. Described is a test method for testing a device under test using a test apparatus that includes a plurality of domain test units provided to correspond respectively to a plurality of blocks of the device under test and a main body unit that controls the domain test units. The test method comprises using the main body unit to generate a reference operation clock and supply the reference operation clock to each domain test unit; using the main body unit to generate a test start signal instructing each domain to start the testing; using the main body unit to supply the test start signal to each domain test unit; causing each domain test unit to generate a test clock based on the reference operation clock; causing each domain test unit to start generating a test signal for testing the corresponding block, based on the test clock, on a condition that the test start signal is received; and causing each domain test unit to use the test signal to test the corresponding block.

While the embodiment of the present invention has been described, the technical scope of the invention is not limited to the above described embodiment. It is apparent to persons skilled in the art that various alterations and improvements can be added to the above-described embodiment. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a device under test having a plurality of blocks operating asynchronously, based on a signal received from outside, the test apparatus comprising:
a plurality of domain test units provided to correspond respectively to the blocks; and
a main body unit that controls the domain test units, wherein
the main body unit includes:
a reference operation clock generating section that generates a reference operation clock supplied to each domain test unit; and
a test start signal generating section that generates a test start signal instructing each domain test unit to start the testing,
each domain test unit includes a test clock generating section that generates a test clock based on the reference operation clock, and generates a test signal for testing the corresponding block based on the test clock obtained by the test clock generating section, and
each domain test unit starts generating the test signal on a condition that the test start signal is received.

2. The test apparatus according to claim 1, wherein
each domain test unit further includes a multiplied test clock generating section that generates a multiplied test clock having a frequency that is an integer multiple of the test clock obtained by the test clock generating section, and
each domain test unit generates the test signal for testing the corresponding block according to a period of the multiplied test clock obtained by the multiplied test clock generating section.

3. A test apparatus comprising a test domain that includes:
a first period signal generating section that receives a phase change signal and adjusts a phase of a period signal generated thereby, based on the phase change signal;
a second period signal generating section that receives, as a reference clock, the period signal generated by the first period signal generating section, and generates a multiplied-period signal with a frequency that is an integer multiple of the frequency of the period signal; and
a testing section that receives, as a test period signal, the multiplied-period signal generated by the second period signal generating section, and tests the device under test according to a period of the test period signal.

4. The test apparatus according to claim 3, further comprising an other test domain that includes:
a third period signal generating section that receives the phase change signal and adjusts a phase of an other period signal generated thereby, based on the phase change signal; and
an other testing section that receives, as an other test period signal, the other period signal generated by the third period signal generating section, and tests an other device under test according to a period of the other test period signal.

5. The test apparatus according to claim 4, wherein
the test period signal of the test domain and the other test period signal of the other test domain are synchronized by commonly using the phase change signal.

6. The test apparatus according to claim 5, wherein
the first period signal generating section generates, as the period signal, a period pulse signal that transitions at a transition timing of an operation clock and phase difference data that indicates a phase difference between a period timing of the period signal and a transition timing of the period pulse signal.

7. The test apparatus according to claim 3, wherein
a multiplication rate of the second period signal generating section is fixed and a period of the multiplied-period signal is changed using a period of the period signal generated by the first period signal generating section.

8. A test method for testing a device under test using a test apparatus that includes a plurality of domain test units provided to correspond respectively to a plurality of blocks of the device under test and a main body unit that controls the domain test units, the test method comprising:
using the main body unit to generate a reference operation clock and supply the reference operation clock to each domain test unit;
using the main body unit to generate a test start signal instructing each domain test unit to start the testing;
using the main body unit to supply the test start signal to each domain test unit;
causing each domain test unit to generate a test clock based on the reference operation clock;
causing each domain test unit to start generating a test signal for testing the corresponding block, based on the test clock, on a condition that the test start signal is received; and
causing each domain test unit to use the test signal to test the corresponding block.

9. The test method according to claim 8, further comprising:
causing each domain test unit to generate a multiplied test clock having a frequency that is an integer multiple of a frequency of the test clock; and
causing each domain test unit to generate a test signal for testing the corresponding block according to a period of the multiplied test clock.

10. A test method comprising:
receiving a phase change signal and adjusting a phase of a generated period signal based on the phase change signal;
receiving the adjusted period signal as a reference clock, and generating a multiplied-period signal with a frequency that is an integer multiple of the frequency of the period signal; and
testing a device under test according to a period of the multiplied-period signal.
